(19) United States
(12) Patent Application Publication
(10) Pub. No.: US 2016/0086909 A1
(43) Pub. Date: Mar. 24, 2016

(54) METHODS AND APPARATUSES FOR SHAPING AND LOOPING BONDING WIRES THAT SERVE AS STRETCHABLE AND BENDABLE INTERCONNECTS

(71) Applicant: MC10, Inc., Lexington, MA (US)

(72) Inventors: David G. Garlock, Derry, NH (US); Xia Li, Wakefield, MA (US); Sanjay Gupta, Bedford, MA (US); Mitul Dalal, South Grafton, MA (US)

(21) Appl. No.: 14/859,680

(22) Filed: Sep. 21, 2015

Related U.S. Application Data
(60) Provisional application No. 62/053,641, filed on Sep. 22, 2014.

(51) Int. Cl. H01L 23/00; H01L 23/498

(52) U.S. Cl. CPC H01L 24/48; H01L 24/78; H01L 24/85; H01L 23/4985; H01L 2224/78611; H01L 2224/7825; H01L 2224/85207; H01L 2224/4813; H01L 2224/48092; H01L 2224/4805

(57) ABSTRACT

A capillary tool for use in feeding, bending, and attaching a bonding wire between a pair of bond pads includes a body and a heating element. The body has an internal tube that extends from a first surface of the capillary tool to a second surface of the capillary tool. In some implementations, the internal tube has a portion with a generally helical shape that includes at least a portion of one complete revolution about a central axis of the body. The heating element is coupled to the body to provide a heat affected zone along a portion of the internal tube that heats the bonding wire as the bonding wire is fed through the internal tube.

### CROSS REFERENCE TO RELATED APPLICATIONS

This application claims the benefit of U.S. Provisional Application No. 62/053,641, filed Sep. 22, 2014, which is hereby incorporated by reference herein in its entirety.

### TECHNICAL FIELD

The present disclosure relates generally to flexible integrated circuits. More particularly, this disclosure relates to methods of and apparatuses for shaping and looping bonding wires that serve as stretchable and bendable interconnects in flexible integrated circuitry.

### BACKGROUND

Integrated circuits (IC) are the cornerstone of the information age and the foundation of today's information technology industries. The integrated circuit, a.k.a. “chip” or “microchip,” is a set of interconnected electronic components, such as transistors, capacitors, and resistors, which are etched or imprinted onto a tiny wafer of semiconducting material, such as, for example, silicon or germanium. Integrated circuits take on various forms including, as some non-limiting examples, microprocessors, amplifiers, Flash memories, application specific integrated circuits (ASICs), static random access memories (SRAMs), digital signal processors (DSPs), dynamic random access memories (DRAMs), erasable programmable read only memories (EPROMs), and programmable logic. Integrated circuits are used in innumerable products, including personal computers, laptop computers, tablet computers, smartphones, televisions, medical instruments, telecommunication and networking equipment, airplanes, watercraft, automobiles, etc.

Advances in integrated circuit technology and microchip manufacturing have led to a steady decrease in chip size and an increase in circuit density and circuit performance. The scale of semiconductor integration has advanced to the point where a single semiconductor chip can hold tens of millions to over a billion devices (e.g., transistors) in a space smaller than a U.S. penny. Moreover, the width of each conducting line in a modern microchip can be made as small as a fraction of a nanometer. The operating speed and overall performance of a semiconductor chip (e.g., clock speed and signal net switching speeds) has concurrently increased with the level of integration. To keep pace with increases in on-chip circuit switching frequency and circuit density, semiconductor packages currently offer higher pin counts, greater power dissipation, more protection, and higher speeds than packages of just a few years ago.

Conventional microchips are generally rigid structures that are not intended to be bent or stretched during normal operating conditions. In addition, IC's are typically mounted on a printed circuit board (PCB) that is as thick or thicker than the IC and similarly rigid. Processes using thick and rigid printed circuit boards are generally incompatible with chips that are thinned or intended for applications requiring elasticity. For example, high quality medical sensing and imaging data has become increasingly beneficial in the diagnoses and treatment of a variety of medical conditions. The conditions can be associated with the digestive system or the cardia-circulatory system and can include injuries to the nervous system, cancer, and the like. To date, most electronic systems that could be used to gather such sensing or imaging data have been rigid and inflexible. These rigid electronics are not ideal for many applications, such as in biomedical devices. Most of biological tissue is soft and curved. The skin and organs are delicate and far from two-dimensional. Other potential applications of electronics systems, such as for gathering data in non-medical systems (e.g., wearable systems measuring movement of a human during sporting activities, etc.), also can be hampered by rigid electronics.

Consequently, many schemes have been proposed for embedding microchips on or in a flexible polymeric substrate. Flexible electronic circuitry employing an elastic substrate material allows the IC to be integrated into innumerable shapes. This, in turn, enables many useful device configurations not otherwise possible with rigid silicon-based electronic devices. However, some flexible electronic circuit designs are unable to sufficiently conform to their surroundings because the interconnecting components are unable to stretch and/or bend in response to conformation changes. These flexible circuit configurations are prone to damage, electronic degradation, and can be unreliable under rigorous use scenarios.

Many flexible circuits now employ stretchable and bendable interconnects that remain intact while the system stretches and bends. An “interconnect” in integrated circuits, for example, electrically couples the IC modules to distribute clock and other signals and provide power/ground throughout the electrical system. Some flexible interconnects capable of bending are formed using etching processes, metal deposition processes, or other wafer-based fabrication processes. While these processes can be used to produce interconnects, the interconnects produced with these methods are generally limited to two-dimensions (i.e., X and Y, but not Z) and the processes themselves are lengthy and thus costly. Further, some flexible interconnects capable of bending are formed using a capillary tool that creates the interconnect as a loop having a length and a height, where the loop is generally in the shape of a “C.” When a product (e.g., a wearable patch/sticker) incorporates a flexible circuit including one or more of such C-shaped interconnects, the desired flexibility of the product is directly correlated with the height of the interconnects. That is, greater flexibility in the interconnect requires a corresponding increase in the height of the interconnects. Thus, greater flexibility results in relatively larger (e.g., thicker) products. This disclosure is directed to solving these and other problems.

### SUMMARY

According to some implementations of the present disclosure, a capillary tool for use in feeding, bending, and attaching a bonding wire between a pair of bond pads includes a body and a heating element. The body has an internal tube that extends from a first surface of the capillary tool to a second surface of the capillary tool. The internal tube has a portion with a generally helical shape that includes at least a portion of one complete revolution about a central axis of the body. The heating element is coupled to the body to provide a heat affected zone along a portion of the internal tube that heats the bonding wire as the bonding wire is fed through the internal tube.

According to some implementations of the present disclosure, a method for attaching a bonding wire between a pair of bond pads includes using a capillary to attach the bonding wire to the first bond pad. The capillary tool is moved towards a second one of the bond pads such that the bonding wire is dispensed from the capillary tool through an internal tube of the capillary tool. The internal tube has a portion with a non-linear shape (e.g., generally coiled or helical shape). The capillary tool is positioned such that a portion of the bonding wire contacts the second bond pad. Using the capillary tool, the bonding wire is attached to the second bond pad.

In some implementations, the internal tube has a first portion or section with a linear or generally linear shape and a second portion or section with a generally non-linear shape (e.g., generally coiled or helical shape, curved, bent, etc.).

According to some implementations of the present disclosure, a method for attaching a bonding wire between a pair of bond pads includes dispensing a portion of the bonding wire from a tip of a capillary tool and forming a free air ball adjacent to the tip of the capillary tool. The free air ball is formed from at least a portion of the dispensed portion of the bonding wire. The capillary tool is positioned such that the free air ball contacts a first one of the bond pads and at least a portion of the tip of the capillary tool. Using the capillary tool, pressure, heat, and/or ultrasonic energy are applied to the free air ball and to the first bond pad to attach the bonding wire to the first bond pad. The capillary tool is moved towards a second one of the bond pads such that the bonding wire is dispensed from the capillary tool through an internal tube of the capillary tool. The internal tube has a portion with a generally helical shape that includes at least a portion of one complete revolution about a central axis of the capillary tool. The generally helical shape causes at least a portion of the dispensed bonding wire to have a generally helical or coiled shape. The capillary tool is positioned such that a portion of the bonding wire contacts the second bond pad. Using the capillary tool, pressure, heat, and/or ultrasonic energy are applied to the portion of the bonding wire contacting the second bond pad to attach the bonding wire to the second bond pad.

According to some implementations of the present disclosure, a method for attaching a bonding wire between a pair of bond pads includes attaching the bonding wire to a first one of the pair of bond pads. A capillary tool is moved around a plurality of posts of a fixture in a generally serpentine path such that the bonding wire is dispensed from the capillary tool through an internal tube of the capillary tool and engages the plurality of posts. The fixture is positioned relative to the pair of bond pads and the capillary tool. The bonding wire is attached to a second one of the pair of bond pads.

According to some implementations of the present disclosure, a method for attaching a bonding wire between a pair of bond pads includes attaching the bonding wire to a first one of the pair of bond pads. A capillary tool is moved around a single post of a fixture at least one time such that the bonding wire is dispensed from the capillary tool through an internal tube of the capillary tool and engages the post. The fixture is positioned relative to the pair of bond pads and the capillary tool. The fixture is removed thereby disengaging the bonding wire from the post. The bonding wire maintains a generally coiled shape after the fixture is removed. The capillary tool is moved towards a second one of the pair of bond pads such that the generally coiled shape of the bonding wire is stretched between the pair of bond pads. The bonding wire is attached to the second bond pad.

According to some implementations of the present disclosure, a method of making an interconnect for electrically connecting a pair of bond pads includes attaching a bonding wire to a first one of the pair of bond pads using a capillary tool. The capillary tool is moved towards a second one of the pair of bond pads such that the bonding wire is dispensed from the capillary tool through an internal tube of the capillary tool. The bonding wire is attached to the second bond pad such that the dispensed bonding wire has a generally arc shape. The dispensed bonding wire is engaged with a fixture such that the fixture causes the dispensed bonding wire to bend into a generally serpentine shape. The fixture is disengaged from the dispensed bonding wire. The dispensed bonding wire maintains the generally serpentine shape after the disengaging.

According to some implementations of the present disclosure, a flexible integrated circuit has a flexible substrate, at least two electrical components, and at least one interconnect electrically connecting two of the at least two electrical components. The flexible integrated circuit is formed by a process including: (i) dispensing a portion of a bonding wire from a tip of a capillary tool; (ii) forming a free air ball adjacent to the tip of the capillary tool, the free air ball being formed from at least a portion of the dispensed portion of the bonding wire; (iii) positioning the capillary tool such that the free air ball contacts a first bond pad of a first one of the at least two electrical components and at least a portion of the tip of the capillary tool; (iv) using the capillary tool, applying pressure, heat, and ultrasonic energy to the free air ball and to the first bond pad to attach the bonding wire to the first bond pad; (v) moving the capillary tool towards a second bond pad of a second one of the at least two electrical components such that the bonding wire is dispensed from the capillary tool through an internal tube of the capillary tool, the internal tube having a portion with a generally helical shape that includes at least a portion of one complete revolution about a central axis of the capillary tool, the generally helical shape causing at least a portion of the dispensed bonding wire to have a generally helical shape; (vi) positioning the capillary tool such that a portion of the bonding wire contacts the second bond pad; and (vii) using the capillary tool, applying pressure, heat, and ultrasonic energy to the portion of the bonding wire contacting the second bond pad to attach the bonding wire to the second bond pad, thereby electrically connecting the first electrical component with the second electrical component.

According to some implementations of the present disclosure, a flexible integrated circuit has a flexible substrate, at least two electrical components, and at least one interconnect electrically connecting two of the at least two electrical components. The flexible integrated circuit is formed by a process including: (i) attaching a bonding wire to a first bond pad of a first one of the at least two electrical components using a capillary tool; (ii) moving the capillary tool around a plurality of posts of a fixture in a generally serpentine path such that the bonding wire is dispensed from the capillary tool through an internal tube of the capillary tool and engages the plurality of posts, the fixture being positioned relative to the first bond pad and the capillary tool; and (iii) attaching the bonding wire to a second bond pad of a second one of the at least two electrical components, thereby electrically connecting the first electrical component with the second electrical component.

According to some implementations of the present disclosure, a flexible integrated circuit has a flexible substrate, at least two electrical components, and at least one interconnect electrically connecting two of the at least two electrical components. The flexible integrated circuit is formed by a process including: (i) attaching a bonding wire to a first bond pad of a first one of the at least two electrical components using a capillary tool; (ii) moving the capillary tool around a single post of a fixture at least one time such that the bonding wire is dispensed from the capillary tool through an internal tube of the capillary tool and engages the post, the fixture being positioned relative to the first bond pad and the capillary tool; (iii) removing the fixture thereby disengaging the bonding wire from the post, the bonding wire maintaining a generally coiled shape after the removing; (iv) moving the capillary tool towards a second bond pad of a second one of the at least two electrical components such that the generally coiled shape of the bonding wire is stretched between the first and the second bond pads; and (v) attaching the bonding wire to the second bond pad, thereby electrically connecting the first electrical component with the second electrical component.

According to some implementations of the present disclosure, a flexible integrated circuit has a flexible substrate, at least two electrical components, and at least one interconnect electrically connecting two of the at least two electrical components. The flexible integrated circuit is formed by a process including: (i) attaching a bonding wire to a first bond pad of a first one of the at least two electrical components using a capillary tool; (ii) moving the capillary tool towards a second bond pad of a second one of the at least two electrical components such that the bonding wire is dispensed from the capillary tool through an internal tube of the capillary tool; (iii) attaching the bonding wire to the second bond pad such that the dispensed bonding wire has a generally arc shape, thereby electrically connecting the first electrical component with the second electrical component; (iv) engaging the dispensed bonding wire with a fixture such that the fixture causes the dispensed bonding wire to bend into a generally serpentine shape; and (v) disengaging the fixture from the dispensed bonding wire, the dispensed bonding wire maintaining the generally serpentine shape after the disengaging.

Additional aspects of the present disclosure will be apparent to those of ordinary skill in the art in view of the detailed description of various implementations, which is made with reference to the drawings, a brief description of which is provided below.

### BRIEF DESCRIPTION OF THE DRAWINGS

FIG. 1A is a perspective view of a capillary tool according to some implementations of the present disclosure;

FIG. 1B is cross-sectional view of the capillary tool of FIG. 1A;

FIG. 1C is a perspective view of the capillary tool of FIG. 1A with a bonding wire positioned therein;

FIG. 1D is a partial perspective view of the capillary tool and bonding wire of FIG. 1C having a portion of the capillary tool removed to better illustrate the bonding wire therein;

FIG. 2A is a perspective view of the capillary tool and bonding wire of FIG. 1C positioned adjacent to a first bond pad of a pair of bond pads according to some implementations of the present disclosure;

FIG. 2B is a perspective view illustrating the capillary tool of FIG. 2A moving towards a second bond pad of the pair of bond pads and a portion of the bonding wire being dispensed therefrom and having a generally helical or coiled shape;

FIG. 2C is a perspective view of the capillary tool and bonding wire of FIG. 2B positioned adjacent to the second bond pad;

FIG. 3A is a perspective view of a capillary tool and a bonding wire positioned adjacent to a first bond pad of a pair of bond pads according to some implementations of the present disclosure;

FIG. 3B is a perspective view illustrating the capillary tool of FIG. 3A moving around posts of a fixture in a generally serpentine path towards a second bond pad of the pair of bond pads and a portion of the bonding wire being dispensed therefrom;

FIG. 3C is a perspective view of the capillary tool and bonding wire of FIG. 3B positioned adjacent to the second bond pad;

FIG. 4A is a perspective view of a capillary tool and a bonding wire positioned adjacent to a first bond pad of a pair of bond pads according to some implementations of the present disclosure;

FIG. 4B is a perspective view illustrating the capillary tool of FIG. 4A moving around a single post of a fixture and a portion of the bonding wire being dispensed therefrom and having a generally coiled shape;

FIG. 4C is a perspective view where the fixture is removed and the capillary tool of FIG. 4A is moving towards a second bond pad of the pair of bond pads and the dispensed bonding wire with the generally coiled shape begins to stretch out;

FIG. 4D is a perspective view of the capillary tool positioned adjacent to the second bond pad and illustrating the stretched out generally coiled shape of the bonding wire;

FIG. 5A is a perspective view of a capillary tool and a bonding wire positioned adjacent to a first bond pad of a pair of bond pads according to some implementations of the present disclosure;

FIG. 5B is a perspective view of the bonding wire of FIG. 5A traced into a temporary interconnect by the capillary tool of FIG. 5A and a fixture for bending the temporary interconnect;

FIG. 5C is a perspective view of the temporary interconnect of FIG. 5B bent by the fixture of FIG. 5B into an interconnect having a generally serpentine shape;

FIG. 6 is a perspective view of a flexible integrated circuit formed according to some implementations of the present disclosure;

FIG. 7 is a plan view of a flexible integrated circuit including a coil according to some implementations of the present disclosure; and

FIG. 8 is a plan view of a flexible integrated circuit including a coil according to some implementations of the present disclosure.

While the present disclosure is susceptible to various modifications and alternative forms, specific implementations have been shown by way of example in the drawings and will be described in detail herein. It should be understood, however, that the present disclosure is not intended to be limited to the particular forms disclosed. Rather, the disclosure is to cover all modifications, equivalents, and alternatives falling within the spirit and scope of the present invention as defined by the appended claims.

### DETAILED DESCRIPTION

While this disclosure is susceptible of implementation in many different forms, there is shown in the drawings and will herein be described in detail some exemplary implementations of the disclosure with the understanding that the present disclosure is to be considered as an exemplification of the principles of the disclosure and is not intended to limit the broad aspect of the disclosure to the implementations illustrated.

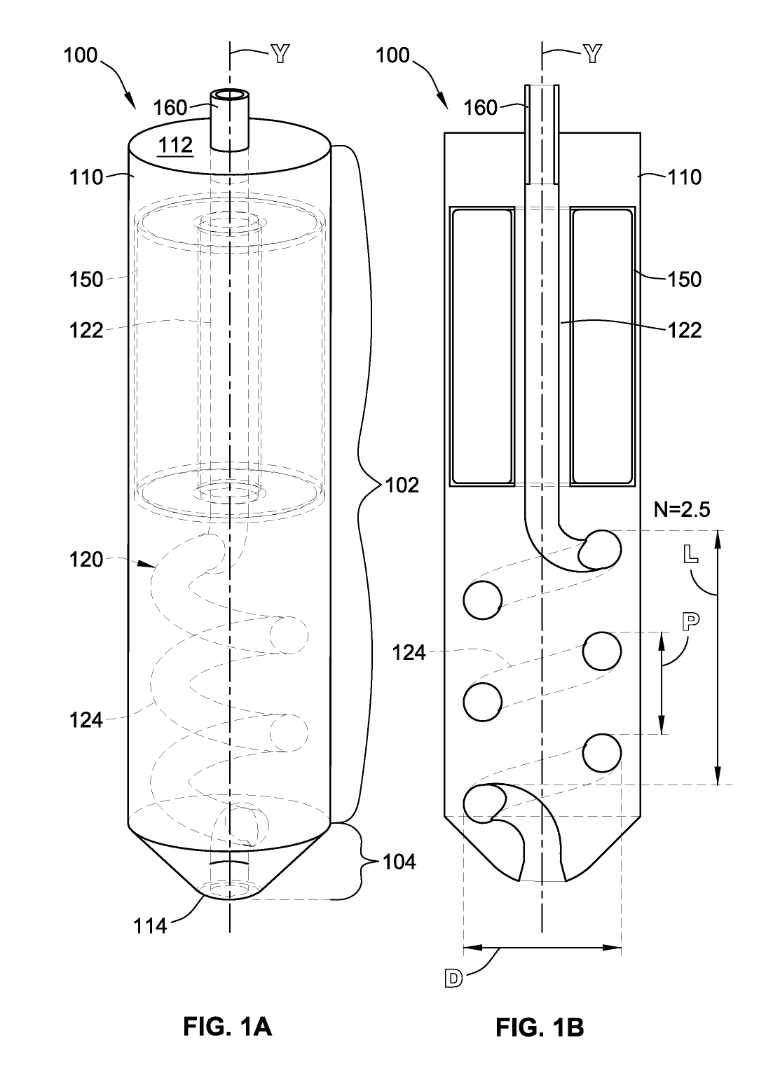

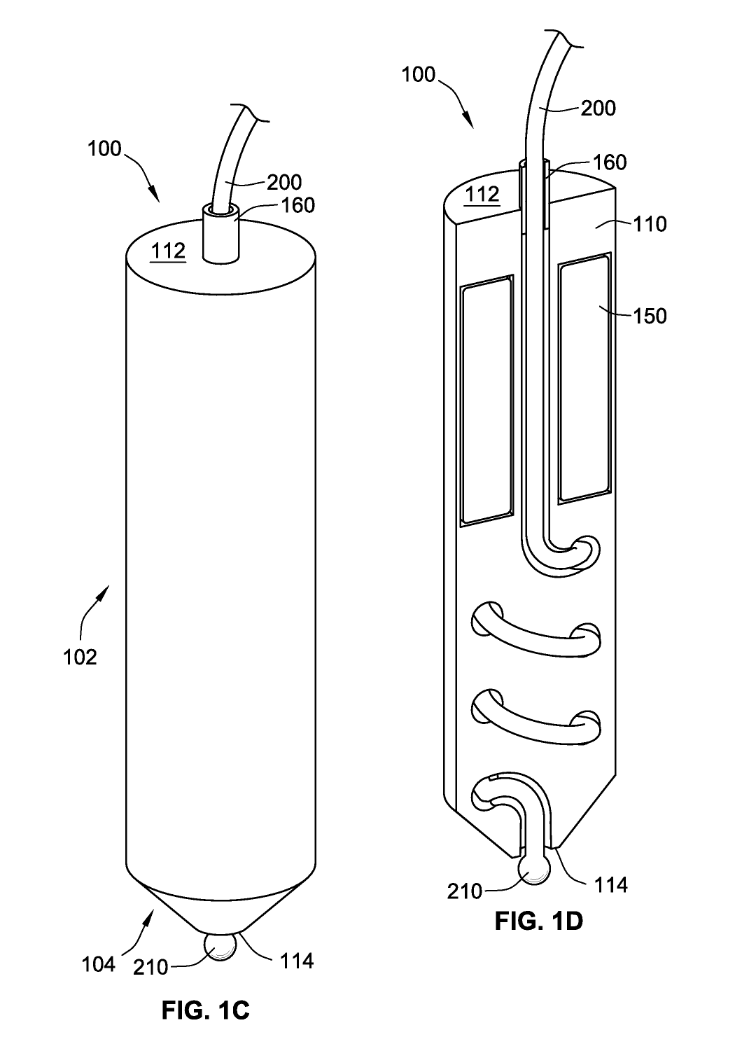

Referring to FIGS. 1A and 1B, a capillary tool 100 for use in feeding, bending, and attaching a bonding wire between a pair of bond pads includes a body 110, a heating element 150, and optionally an ultrasonic transducer 160. The body 110 of the capillary tool 100 includes a first portion 102 and a second portion 104. The first portion 102 of the body has a generally cylindrical shape and the second portion 104 has a generally conical shape. The second portion 104 is also referred to as a tip of the capillary tool 100.

The body 110 of the capillary tool 100 has an internal tube 120, which can also be referred to as a capillary or capillary channel, that extends from a first surface 112 of the capillary tool 100 to a second surface 114 of the capillary tool 100. In the illustrated implementation, the first surface 112 is a top surface and the second surface 114 is a bottom surface, but the internal tube 120 may begin and/or end from other surfaces of the capillary tool 100 (e.g., side surface, etc.). The internal tube 120 includes a first section 122 that has a generally straight or linear shape and a second section 124 that has a generally helical or coiled shape. As shown, the first section 122 of the internal tube 120 passes through or is adjacent to the heating element 150, although some or all of the second section 124 of the internal tube 120 can likewise pass through or be adjacent to the heating element 150.

The generally helical shape of the second section 124 of the internal tube 120 can be right handed or left handed. As shown, the generally helical shape of the second section 124 of the internal tube 120 includes about two and a half complete revolutions about a central axis, Y, of the body 110, although any number of complete and/or partial revolutions of the generally helical shape are contemplated. For example, the generally helical shape of the second section 124 of the internal tube 120 can have one-quarter of a complete revolution about the central axis, Y, of the body 110. For another example, the generally helical shape of the second section 124 of the internal tube 120 can have one half of a complete revolution about the central axis, Y, of the body 110. For another example, the generally helical shape of the second section 124 of the internal tube 120 can have one complete revolution about the central axis, Y, of the body 110. For another example, the generally helical shape of the second section 124 of the internal tube 120 can have two complete revolutions about the central axis, Y, of the body 110. For another example, the generally helical shape of the second section 124 of the internal tube 120 can have four complete revolutions about the central axis, Y, of the body 110. Thus, it should be understood that any number of complete and/or partial revolutions about the central axis, Y, can be included in the second section 124 of the internal tube 120.

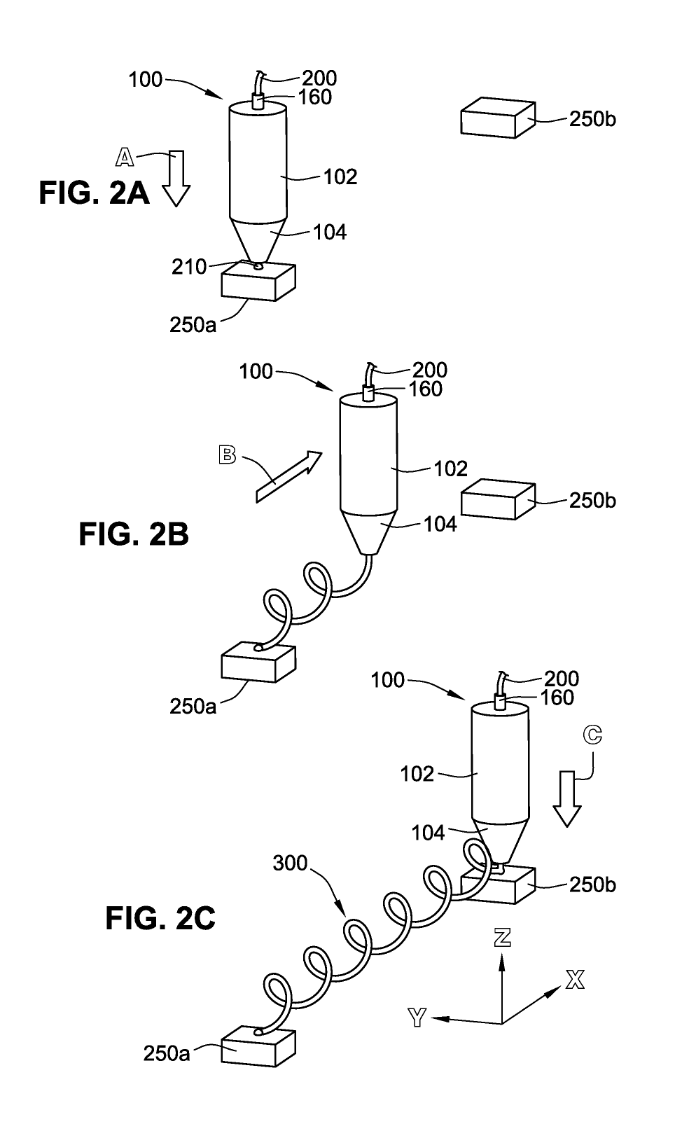

As will be further described herein, the generally helical shape of the second section 124 of the internal tube 120 causes at least a portion of a bonding wire 200 (FIGS. 1C and 1D) that is dispensed from the capillary tool 100 to have a generally helical shape (shown in FIGS. 2B and 2C) that is a function of the generally helical shape of the second section 124 of the internal tube 120. In some implementations, the number of revolutions is modified when designing the capillary tool 100 depending on the characteristics of the material of the bonding wire 200 and/or the specifications of the heating element 150 and/or a variety of other factors/parameters such as the desired characteristics of the bonding wire 200 dispensed therefrom.

As shown in FIGS. 1A and 1B, the generally helical shape of the second section 124 of the internal tube 120 has a generally constant pitch, P, where pitch is the width of one complete revolution or turn of the generally helical shape of the second section 124 of the internal tube 120, measured parallel to the central axis, Y. However, in alternative implementations (not shown), the generally helical shape of the second section 124 of the internal tube 120 can have a varying pitch, a first portion with a first pitch and a second portion with a second pitch, etc.

As illustrated, the heating element 150 is positioned entirely within the first portion 102 of the body 110, although the heating element 150 can be positioned such that a portion of the heating element 150 is in the first portion 102, the second portion 104, outside the body 110, or any combination thereof. The heating element 150 provides a heat affect zone (HAZ) along at least a portion of the first section 122 of the internal tube 120. The heating element 150 is used to heat the bonding wire 200 as the bonding wire passes through the HAZ of the internal tube 120. Depending on the desired output of the capillary tool 100, the temperature of the heating element 150 and the HAZ of the internal tube 120 therein can be increased and/or decreased during, before, and/or after the bonding wire 200 is dispensed through the capillary tool 100. In some implementations, the heating element 150 is configured to heat the bonding wire 200 to a temperature that is greater than the glass transition temperature (T_{g}) of the material and/or materials that form the bonding wire 200.

As illustrated, the optional ultrasonic transducer 160 is partially protruding from the first portion 102 of the body 110, although the ultrasonic transducer 160 can be positioned such that a portion of the ultrasonic transducer 160 is in the first portion 102, the second portion 104, outside the body 110, or any combination thereof. The ultrasonic transducer 160 provides ultrasonic energy that can be transmitted to any portion of the capillary tool 100, a bond pad engaged by the capillary tool 100, the bonding wire 200, or any combination thereof, to aid in attaching the bonding wire 200 to, for example, the bond pad as described herein. While the illustrated ultrasonic transducer 160 has a generally cylindrical tube-like shape, the ultrasonic transducer 160 can any shape, such as, for example, cube-like shape, rectangular-like shape, etc.

As shown in FIGS. 1C and 1D, the bonding wire 200 is positioned through the ultrasonic transducer 160 and within the internal tube 120 of the capillary tool 100 and ready to be dispensed from a source (e.g., a spool of bonding wire) through the capillary tool 100. To start attaching the bonding wire between a pair of bond pads, thereby creating an interconnect, a portion of the bonding wire 200 is dispensed from the tip 104 of the capillary device 100. According to some implementations, the heating element 150 heats the bonding wire 200 such that a free air ball 210 forms adjacent to the tip 104 of the capillary tool 100. In alternative implementations, a separate source of heat and/or energy (not shown) is used to cause the free air ball 210 to form.

After the free air ball 210 is formed, the interconnect is ready to be formed and attached between the pair of bond pads. Such a method of attaching a bond wire between a pair of bond pads to create an interconnect using the capillary tool 100 (FIGS. 1A-1D) is illustrated and described in reference to FIGS. 2A-2C. Referring to FIG. 2A, the capillary tool 100 and bonding wire 200 of FIGS. 1C and 1D are shown relative to a pair of bond pads 250a,b. Specifically, the capillary tool 100 is positioned such that the free air ball 210 contacts the first bond pad 250a and at least a portion of the tip 104. To attach the bonding wire 200 to the first bond pad 250a, heat, pressure, and/or ultrasonic energy may be used. Specifically, heat is derived at least in part from the heating element 150; pressure is derived at least in part by moving/forcing the tip 104 of the capillary tool downward in the direction of arrow A; and ultrasonic energy is derived at least in part by the ultrasonic transducer 160. According to some implementations, the combination of the heat, pressure, and/or ultrasonic energy attach the free air ball 210, and thus the bonding wire 200, to the first bond pad 250a. Such a process can be referred to as thermosonic welding. Various other methods of attaching the bonding wire 200 to the first bond pad 250a are contemplated and can be implemented in the described processes/methods of the present disclosure. For example, another method of attaching the bonding wire 200 to the first bond pad 250a includes the use of heat and pressure, but not ultrasonic energy.

With the bonding wire 200 attached to the first bond pad 250a (FIG. 2A), the capillary tool 100 is moved generally in the direction of arrow B (FIG. 2B) towards the second bond pad 250b. The moving of the capillary tool 100 causes the bonding wire 200 to be dispensed through the internal tube 120 of the capillary tool 100 and out of the tip 104 at the second surface 114 of the capillary tool 100. As described above, the generally helical shape of the second section 124 of the internal tube 120 causes the bonding wire 200 to be dispensed with a generally helical shape that is a function of the generally helical shape of the second section 124 of the internal tube 120 and other parameters/factors. It is noted that the direction of movement of the capillary tool 100 in the direction of arrow B does not have to be, or is not, exactly horizontal. Rather, the capillary tool 100 can take an arc-like path/trace or take any other path/trace from the first bond pad 250a to the second bond pad 250b, so long as the capillary tool 100 moves from the first bond pad 250a to the second bond pad 250b in some fashion. In some implementations, the path taken/traced by the capillary tool 100 aids in the dispensing of the bonding wire 200 therefrom.

Specifically, the shape and/or size of the dispensed portion of the bonding wire 200 is a function of a variety of parameters, such as, for example, the size and shape of the second section 124 of the internal tube 120 having the generally helical shape, the type of wire used for the bonding wire 200 (e.g., gold wire, copper wire, other metal wire, or any combination thereof), the size/diameter of the bonding wire 200, the mechanical and/or physical properties such as Young's modulus of the bonding wire 200, the temperature within the heat affected zone (HAZ), the length of the HAZ, the path traveled between the bond pads by the capillary tool 100, the speed that the capillary tool 100 moves from bond pad to bond pad, etc., or any combination thereof.

The size and shape of the second section 124 of the internal tube 120 having the generally helical shape can be defined in terms of geometry parameters including a revolution diameter, D, a number of complete and/or partial revolutions, N, and a total length of the revolutions, L. In some implementations of the present disclosure, the revolution diameter, D, can be about one hundred micrometers, about five hundred micrometers, about one millimeter, etc. In some implementations of the present disclosure, the revolution diameter, D, can be between about fifty micrometers to about two millimeters. In some implementations of the present disclosure, the number of complete and/or partial revolutions, N, can be about two, about five, about ten, about fifty, etc. In some implementations of the present disclosure, the number of complete and/or partial revolutions, N, can be between about 0.5 and about two hundred. In some implementations of the present disclosure, the total length of the revolutions, L, can be about five hundred micrometers, about one millimeter, about five millimeters, about one centimeter, etc. In some implementations of the present disclosure, the total length of the revolutions, L, can be between about two hundred micrometers to about three centimeters.

Referring back to FIG. 1B, the geometry parameters D, N, and L, for the capillary tool 100 are shown where N is about 2.5. Various other methods of defining and measuring the geometry parameters are contemplated. It is noted that the geometry parameters D, N, and L, for the capillary tool 100 do not necessarily correspond in a one-to-one fashion with similar geometry parameters of the dispensed portion of the bonding wire 200. That is, in some implementations, the revolution diameter, D, of the second section 124 of the internal tube 120 having the generally helical shape can be the same as, larger than, or smaller than the diameter of the dispensed bonding wire 200 having a generally helical shape (see FIG. 2C). Similarly, for example, in some implementations, the number of revolutions, N, of the second section 124 of the internal tube 120 having the generally helical shape can be the same as, more than, or less than the number of revolutions of the dispensed bonding wire 200 having a generally helical shape (see FIG. 2C). Thus, the generally helical shape of the dispensed portion of the bonding wire 200 can be different than the generally helical shape of the second section 124 of the internal tube 120.

The capillary tool 100 continues to move in the direction of arrow B (FIG. 2B) until the capillary tool 100 approaches the second bond pad 250b. As shown in FIG. 2C, the capillary tool 100 is then moved generally in the direction of arrow C to position a portion of the bonding wire 200 in contact with the second bond pad 250b. The capillary tool 100 is then used to apply heat, pressure, and/or ultrasonic energy to the portion of the bonding wire 200 contacting the second bond pad 250b to attach the bonding wire 200 to the second bond pad 250b in a way similar to how the free air ball 210 was attached to the first bond pad 250a.

With the bonding wire 200 attached to the first and the second bond pads 250a, 250b, the capillary tool 100 causes the bonding wire 200 to split, snap, or break near the second bonding pad 250b such that the bonding wire 200 remains attached to the second bond pad 250b and such that the capillary tool 100 can move onto attaching the bonding wire 200 between a different pair of bond pads (not shown). The dispensed portion of the bonding wire 200 that is attached between the first and the second bond pads 250a, 250b is referred to as an interconnect 300.

As shown in FIG. 2C, the interconnect 300 connects the first bond pad 250a with the second bond pad 250b. As the interconnect 300 is at least partially formed of an electrically conductive material, the interconnect 300 electrically couples the first bond pad 250a to the second bond pad 250b. The bond pads 250a, 250b can be electrically coupled with or integral with any type of and/or any portion of an integrated circuit (IC). A shown, the interconnect 300 has a generally helical shape that is flexible and bendable. The generally helical shape of the interconnect 300 allows the bond pads 250a, 250b (and the electronics to which each is attached) to be moved in three-dimensional space (e.g., X direction, Y direction, and/or Z direction) relative to each other without breaking the attachment of the interconnect 300 to either of the bond pads 250a, 250b. That is, for example, the interconnect 300 is able to stretch and elongate along its X axis. Further, for example, the interconnect 300 is able to compress and shrink along its X axis. Yet even further, for example, the interconnect 300 is able to bend and flex about its Y and Z axes.

As discussed above, the number of complete revolutions of the interconnect 300 is a function of the parameters discussed above, including the path traveled between the bond pads 250a, 250b by the capillary tool 100. The number of revolutions or coils of the interconnect 300 will increase with an increase in the distance between the bond pads 250a, 250b. Thus, in some implementations, depending on the above parameters, the interconnect 300 will have two or more complete revolutions or curls. In some other implementations as shown in FIG. 2C, the interconnect 300 will have about six complete revolutions or curls. In some other implementations, the interconnect 300 will have ten or more complete revolutions or curls. In yet some other implementations, the interconnect 300 will have thirty or more complete revolutions or curls.

While the above implementations involve the use of the capillary tool 100 having the second section 124 of the interior tube 120 with a generally non-linear shape, such as, for example, a helical shape, in lieu of using such a capillary tool 100, a capillary tool 400 without such a generally helical shape interior tube can be used in combination with a fixture (e.g., fixture 461, 561) to create a flexible and bendable interconnect between a pair of bond pads.

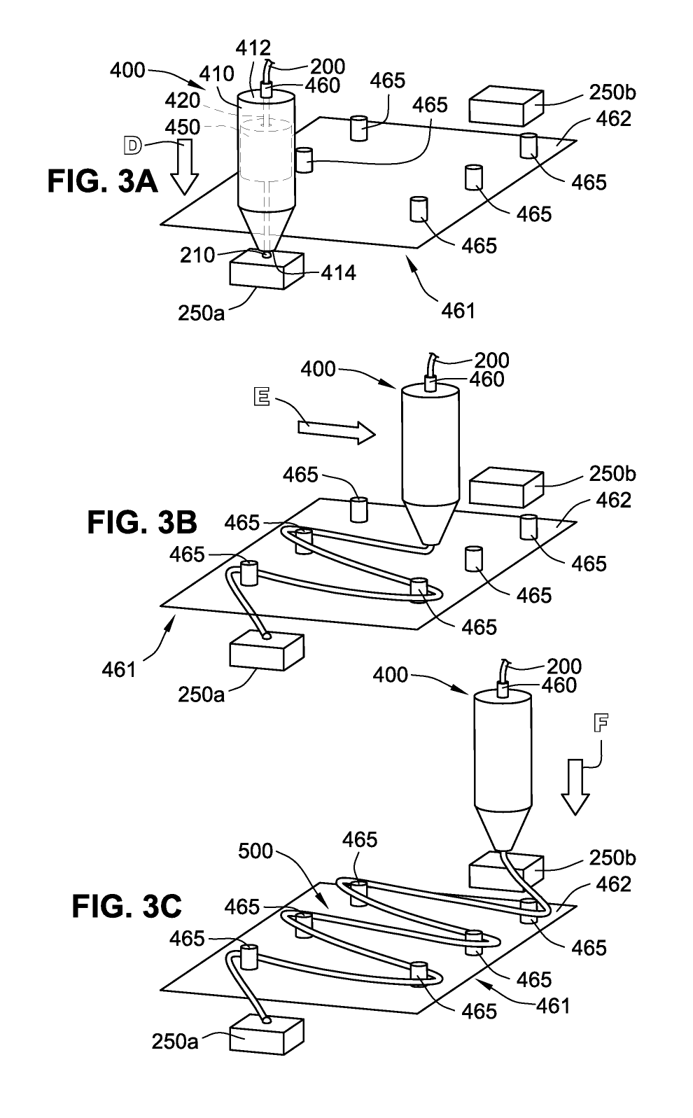

Referring to FIGS. 3A-3C, the capillary tool 400 is shown for use in feeding, bending, and attaching a bonding wire 200 between a pair of bond pads 250a, 250b, where like reference numbers are used for like components described herein. The capillary tool 400 is similar to the capillary tool 100 in that the capillary tool 400 includes a body 410, a heating element 450, and optionally an ultrasonic transducer 460 that are the same as, or similar to, the body 110, the heating element 150, and the ultrasonic transducer 160. However, the capillary tool 400 also includes an internal tube 420 that does not include a second section with a generally helical shape like the internal tube 120 of the capillary tool 100. Rather, the capillary tool 400 includes the internal tube 420 having a generally straight or linear shape from a first surface 412 of the body 410 to a second surface 414 of the body 410.

In order to provide a flexible and bendable interconnect between the bonding pads 250a, 250b shown in FIGS. 3A-3C, the capillary tool 400 is used to attach the bonding wire 200 to the first bond pad 250a in the same, or similar, manner described above in connection with the capillary tool 100. Specifically, a free air ball 210 is formed and attached to the first bond pad 250a as the capillary tool 400 moves in the direction of arrow D applying heat, pressure, and ultrasonic energy.

With the bonding wire 200 attached to the first bond pad 250a (FIG. 3A), the capillary tool 400 is moved around a multitude of posts 465 of a fixture 461 in a generally non-linear path such as a generally serpentine path (e.g., arrow E in FIG. 3B). The posts 465 of the fixture 461 are attached to a common base plate 462 such that the posts 465 are positioned in a fixed and known location relative to each other. Further, the fixture 461 is positioned relative to the pair of bond pads 250a, 250b and the capillary tool 400 in a known relative orientation and position. As such, according to some implementations, the capillary tool 400 can move along a preprogrammed serpentine path around the posts 465 to provide a repeatable interconnect.

The moving of the capillary tool 400 in the generally serpentine path causes the bonding wire 200 to be dispensed through the internal tube 420 of the capillary tool 400 and out of a tip at the second surface 414 of the capillary tool 400. As the capillary tool 400 moves around the posts 465, the bonding wire 200 is caused to engage the posts 465 and bend/deform therearound. The heating element 450 can be used to heat the bonding wire 200 so that as the bonding wire 200 is dispensed around the posts 465, the temperature of the dispensed bonding wire 200 aids in the bending and/or deformation of the bonding wire 200 therearound.

The capillary tool 400 continues to move in the generally serpentine path (FIG. 3B) until the capillary tool 400 approaches the second bond pad 250b. As shown in FIG. 3C, the capillary tool 400 is then moved generally in the direction of arrow F to position a portion of the bonding wire 200 in contact with the second bond pad 250b. The capillary tool 400 is then used to apply heat, pressure, and/or ultrasonic energy to the portion of the bonding wire 200 contacting the second bond pad 250b to attach the bonding wire 200 to the second bond pad 250b.

With the bonding wire 200 attached to the first and the second bond pads 250a, 250b, the capillary tool 400 may cause the bonding wire 200 to split, snap, or break near the second bonding pad 250b similar to that described above in connection with FIG. 2C. As such, the capillary tool 400 is free to move onto attaching the bonding wire 200 between a different pair of bond pads (not shown) using the fixture 461 or a similar fixture in a repeatable fashion. That is, after the bonding wire 200 is attached to the second bond pad 250b, the fixture can be removed, thereby disengaging the bonding wire 200 from the posts 465. Once the fixture is disengaged, the bonding wire 200 maintains its generally serpentine shape due, in part, to the bonding wire 200 having a certain degree of memory. As shown in FIG. 3C, the dispensed portion of the bonding wire 200 that is attached between the first and the second bond pads 250a, 250b is referred to as an interconnect 500.

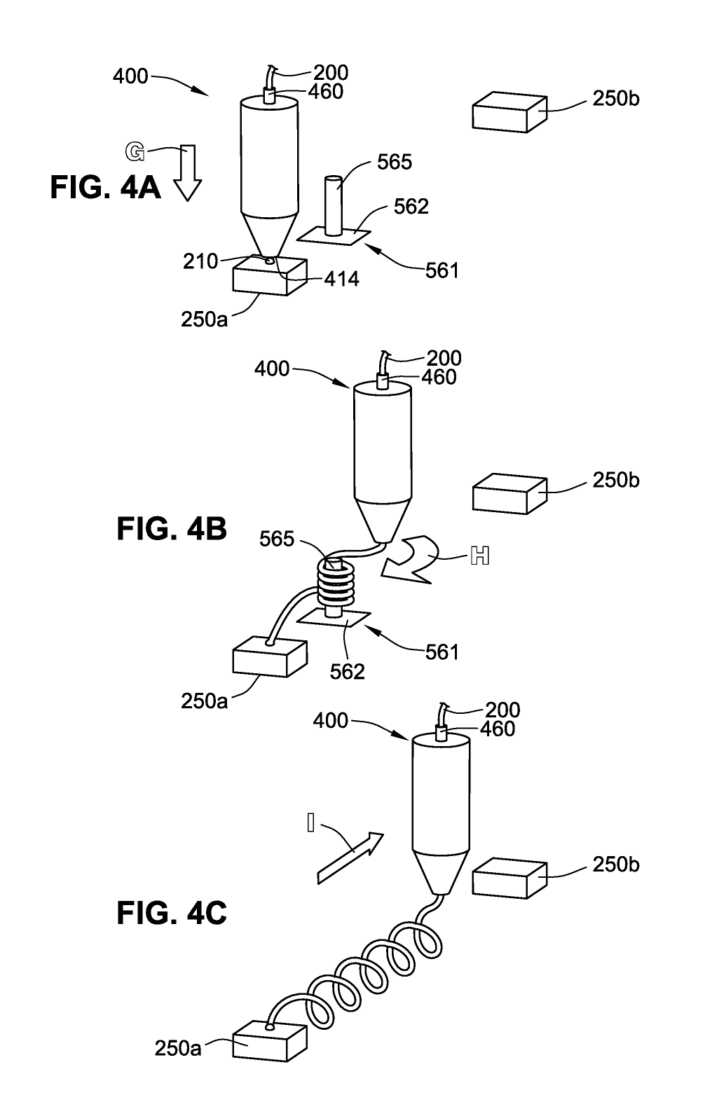

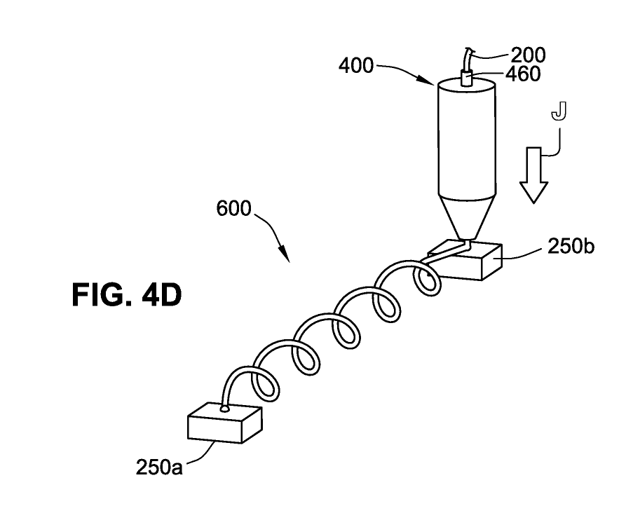

Referring now to FIGS. 4A-4D, the capillary tool 400 is shown for use in feeding, bending, and attaching a bonding wire 200 between a pair of bond pads 250a, 250b using a fixture 561, where like reference numbers are used for like components described herein. The capillary tool 400 is used in a similar fashion as described in connection with FIGS. 3A-3C, however, instead of moving the capillary tool 400 in a generally serpentine path, the capillary tool 400 is moved around a single post 565 attached to a base plate 562 of the fixture 561 at least one time to create one or more coils of the bonding wire 200 therearound.

Specifically, referring to FIG. 4A, a free air ball 210 is formed and attached to the first bond pad 250a as the capillary tool 400 moves in the direction of arrow G applying heat, pressure, and/or ultrasonic energy.

With the bonding wire 200 attached to the first bond pad 250a (FIG. 4A), the capillary tool 400 is moved around the post 565 of the fixture 561 at least one time in the direction of arrow H (FIG. 4B) to create one or more coils of the bonding wire 200 around the post 565. The fixture 561 is positioned relative to the pair of bond pads 250a, 250b and the capillary tool 400 in a known relative orientation and position. As such, according to some implementations, the capillary tool 400 can move along a preprogrammed path around the post 565 to provide a generally repeatable interconnect.

The moving of the capillary tool 400 around the post 565 causes the bonding wire 200 to be dispensed through the internal tube 420 of the capillary tool 400 and out of a tip at the second surface 414 of the capillary tool 400. As the capillary tool 400 moves around the post 565, the bonding wire 200 is caused to engage the post 565 and bend/deform therearound. The heating element 450 of the capillary tool 400 can be used to heat the bonding wire 200 so that as the bonding wire 200 is dispensed around the post 565, the temperature of the dispensed bonding wire 200 aids in the bending and/or deformation of the bonding wire 200 therearound.

The capillary tool 400 continues to move around the post 565 generally in the direction of arrow H (FIG. 4B) until a desired number of coils of the bonding wire 200 are made. After the desired number of coils are made, the fixture 561 is removed, thereby disengaging the bonding wire 200 from the post 565. Once the fixture 561 is disengaged, the bonding wire 200 maintains its generally coiled shape due, in part, to the bonding wire 200 having a certain degree of memory. It is contemplated that in some implementations of the present disclosure, the capillary tool 400 moves around the post 565, in the direction of arrow H, in a single generally-horizontal plane such each additional one of the coils of the bonding wire 200 is formed with a slightly larger diameter than the previous coil. Alternatively, the capillary tool 400 can move around the post 565, in the direction of arrow H, in multiple generally-horizontal planes such that each additional one of the coils of the bonding wire 200 is formed with about the same diameter as the previous coil(s) and at a slightly different elevation along the post 565.

With the fixture 561 out of the way, the capillary tool 400 is moved generally in the direction of arrow I toward the second bond pad 250b. As the capillary tool is moved in the direction of arrow I, the coils of the bonding wire 200 begin to stretch and align in a generally coiled or helical shape as shown in FIG. 4D. Further, as shown in FIG. 4D, the capillary tool 400 is then moved generally in the direction of arrow J to position a portion of the bonding wire 200 in contact with the second bond pad 250b. The capillary tool 400 is then used to apply heat, pressure, and/or ultrasonic energy to the portion of the bonding wire 200 contacting the second bond pad 250b to attach the bonding wire 200 to the second bond pad 250b.

With the bonding wire 200 attached to the first and the second bond pads 250a, 250b, the capillary tool 400 may cause the bonding wire 200 to split, snap, or break near the second bonding pad 250b similar to that described above in connection with FIG. 2C. As such, the capillary tool 400 is free to move onto attaching the bonding wire 200 between a different pair of bond pads (not shown) using the fixture 561 or a similar fixture in a generally repeatable fashion. As shown in FIG. 4D, the dispensed portion of the bonding wire 200 that is attached between the first and the second bond pads 250a, 250b is referred to as an interconnect 600.

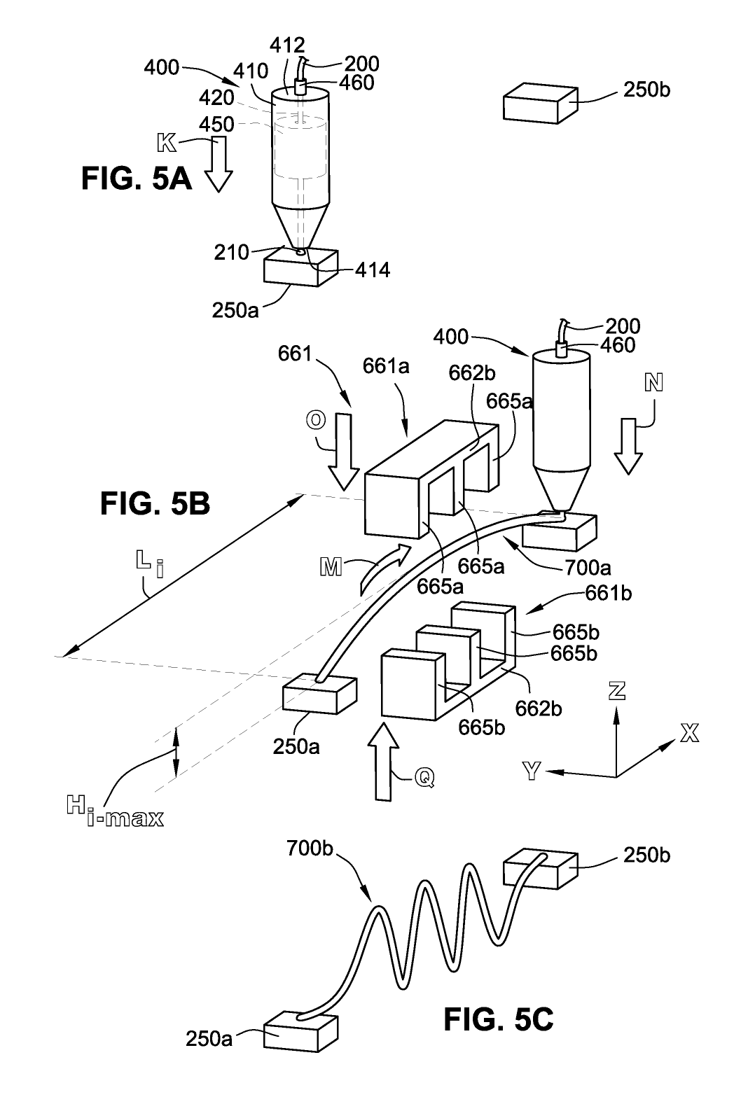

Referring now to FIGS. 5A-5C, the capillary tool 400 is shown for use in feeding and attaching a bonding wire 200 between a pair of bond pads 250a, 250b using a fixture 661 (FIG. 5B), where like reference numbers are used for like components described herein. The capillary tool 400 is used in a similar fashion as described in connection with FIGS. 3A-3C, however, instead of moving the capillary tool 400 in a generally serpentine path around posts of a fixture (e.g., fixture 461, 561), the capillary tool 400 is moved in a generally arc-shaped path, in the direction of arrow M (FIG. 5B), from the first bond pad 250a to the second bond pad 250b, thereby forming a temporary interconnect 700a therebetween (shown in FIG. 5B) having a length, Lᵢ, and a maximum height, Hᵢ₋ₘₐₓ. By “temporary” it is meant that the temporary interconnect 700a is not considered the final form of the interconnect as the temporary interconnect 700a will be modified by the fixture 661 to have a different shape to form an interconnect 700b (FIG. 5C).

Specifically, referring to FIG. 5A, a free air ball 210 is formed and attached to the first bond pad 250a as the capillary tool 400 moves in the direction of arrow K applying heat, pressure, and/or ultrasonic energy. With the bonding wire 200 attached to the first bond pad 250a (FIG. 5A), the capillary tool 400 is moved in a generally arc-shaped path in the direction of arrow M (FIG. 5B) to create the temporary interconnect 700a having the length, L, and the maximum height, Hᵢ₋ₘₐₓ. The moving of the capillary tool 400 between the bond pads 250a,b causes the bonding wire 200 to be dispensed through the internal tube 420 of the capillary tool 400 and out of a tip at the second surface 414 of the capillary tool 400. Further, as shown in FIG. 5B, the capillary tool 400 is then moved generally in the direction of arrow N to position a portion of the bonding wire 200 in contact with the second bond pad 250b. The capillary tool 400 is then used to apply heat, pressure, and/or ultrasonic energy to the portion of the bonding wire 200 contacting the second bond pad 250b to attach the bonding wire 200 to the second bond pad 250b.

With the bonding wire 200 attached to the first and the second bond pads 250a, 250b, the capillary tool 400 may cause the bonding wire 200 to split, snap, or break near the second bonding pad 250b similar to that described above in connection with FIG. 2C. As such, the capillary tool 400 is free to move onto attaching the bonding wire 200 between a different pair of bond pads (not shown) using the fixture 661 or a similar fixture in a generally repeatable fashion.

After the bonding wire 200 is caused to split, snap, or break, or prior to such action, the fixture 661 is used to bend the bonding wire 200 into a generally serpentine shape or a generally zigzag shape as shown in FIG. 5C. Specifically, as shown in FIG. 5B, the fixture 661 includes a first bending member 661a and a second bending member 661b. The first bending member 661a includes a plurality of posts or fingers 665a coupled to a base 662a. Similarly, the second bending member 661b includes a plurality of posts or fingers 665b coupled to a base 662b.

To modify the bond wire 200 traced between the bond pads 250a,b (FIG. 5A) such that the bond wire 200 has a generally serpentine shape (shown in FIG. 5C), the first and the second bending members 661a,b are moved towards each other in the direction of arrows O and Q, respectively. Specifically, the first and the second bending members 661a,b are offset from each other such that the fingers 665a, 665b alternate as best shown in FIG. 5B. Thus, as the first and the second bending members 661a,b are pinched together, the bonding wire 200 is forced between the fingers 665a and 665b and bent and/or forced into the generally serpentine shape shown in FIG. 5C.

While each of the bending members 661a,b are shown as including three fingers 665a,b, each of the bending members 661a,b can include any number of fingers 665a,b. For example, each of the bending member 661a,b can include two fingers, four fingers, five fingers, ten fingers, etc. Additionally, the distance between each of the fingers 665a,b can be modified to, for example, control the pitch of the formed serpentine shape of the interconnect 700b. The spacing between each of the fingers 665a,b can be adjusted using a mechanism (not shown), such as, for example, a sliding mechanism between the fingers 665a,b and the base 662a,b. Specifically, for example, each of the fingers can be slidably engaged with the base 662a,b (e.g., along a longitudinal axis of the base) and lockable in place (e.g., using a set screw or the like). In such alternative implementations, the fingers can slidably engage the base in a tongue-and-groove fashion, or using any other mechanical mechanism. It is contemplated that such a spacing adjustment between the fingers 665a,b can occur prior to, during, and/or after the bending members 661a,b are pinched together. That is, in some implementations, the spacing between the fingers 665a,b is set and then the bending members 661a,b are pinched together. In some other implementations, the fingers 665a,b have a first spacing therebetween, then the bending members 661a,b are pinched together, then the fingers 665a,b are moved/adjusted to have a second spacing therebetween that is different than the first spacing, and then the bending members 661a,b are unpinched/separated. Various other methods/schemes of adjusting the spacing between the fingers 665a,b and pinching/unpinching to form a variety of interconnect shapes are contemplated.

As shown, the interconnect 700b (FIG. 5C) is generally in a X-Z plane; however, the interconnect 700 can be traced (e.g., connected between the first and second bond pads 250a,b) in any plane. For example, in some implementations, the interconnect 700b can be positioned in the X-Y plane. In such an alternative, the positioning of the fixture 661 is modified to move in a correspondingly different plane to capture and bend the bonding wire 200 accordingly.

The bonding wire 200 described throughout this disclosure can include one or more electrically conductive materials. In some implementations, the bonding wire 200 includes electrically conductive materials, such as, for example, aluminum, stainless steel, a transition metal, a metal alloy, including alloys with carbon, copper, silver, gold, platinum, zinc, nickel, titanium, chromium, or palladium, a semiconductor-based conductive material, including a silicon-based conductive material, indium tin oxide or other transparent conductive oxide, or Group III-IV conductors (including GaAs), or any combination thereof.

In some other implementations, the electrically conductive materials are coated with one or more electrically insulating materials, such as, for example, a polymer or polymeric material, such as, a polyimide, a polyethylene terephthalate (PET), a silicone, or a polyeurethane, plastics, elastomers, thermoplastic elastomers, elastoplastics, thermostats, thermoplastics, acrylates, acetal polymers, biodegradable polymers, cellulosic polymers, fluoropolymers, nylons, polyacrylonitrile polymers, polyamide-imide polymers, polyarylates, polybenzimidazole, polybutylene, polycarbonate, polyesters, polyetherimide, polyethylene, polyethylene copolymers and modified polyethylenes, polyketones, polymethyl methacrylate, polymethylpentene, polyphenylene oxides and polyphenylene sulfides, polyphthalamide, polypropylene, polyurethanes, styrenic resins, sulphone based resins, vinyl-based resins, or any combinations thereof.

In some implementations, the capillary tools 100, 400 of the present disclosure and/or one or more of the fixtures 461, 561, 661 of the present disclosure, and/or a separate device includes a dispensing component that dispenses certain material (e.g., one or more of the electrically insulating materials described herein) that encapsulates the interconnect 300, 500, 600, 700b, etc. (e.g., formed from the bonding wire 200 that is made of an electrically conductive material) to aid in solidifying the interconnect and/or aid in maintaining the shape (e.g., generally serpentine, generally helical, etc.) of the interconnect. In some implementations, the dispensed encapsulating material can be electrically insulating and can be a polymer such as silicone, polyurethane, and/or a low density polyester. In some implementations, the Young's modulus of the dispensed encapsulating material can be in the range of up to about 0.1 Kpa, up to about ten Kpa, up to about 0.1 Mpa, up to about ten Mpa, etc.

In some implementations, the electrically insulating materials electrically insulate the bonding wire 200 up to a supply voltage, such as, for example, 3.3 volts, 6.7 volts, etc.

The interconnects 300, 500, 600 described herein and formed from the bonding wire 200 can be made of the above described electrically conductive materials and/or electrically insulating materials. Regardless of the materials used to form the interconnects 300, 500, 600, according to some implementations, each of the interconnects 300, 500, 600 can have a thickness of from about 0.1 μm to about 100 μm including, for example, about 0.1 μm, about 0.3 μm, about 0.5 μm, about 0.8 μm, about 1 μm, about 1.5 μm, about 2 μm, about 5 μm, about 9 μm, about 12 μm, about 25 μm, about 50 μm, about 75 μm, about 100 μm, or any other thickness.

As described herein, the heating element 150, 450 is used to heat the bonding wire 200. According to some implementations, the heating of the bonding wire 200 transforms the bonding wire 200 into a molten glass-like state when heated above its glass transition temperature (T_{g}). The capillary tools 100, 400 of the present disclosure work with the heating element 150, 450 to heat the bonding wire 200 above its glass transition temperature (T_{g}) prior to making any “shaping move.” For example, prior to dispensing the bonding wire 200 around each of the posts 465 in FIGS. 3A-3C, the heating element 450 heats the bonding wire 200 past its glass transition temperature (T_{g}). Then the capillary tool 400 makes the “shaping move” around the post 465. Then, after the bonding wire 200 cools below its glass transition temperature (T_{g}), the materials of the bonding wire 200 transition back to their solid state and in turn memorize its shape, thereby giving the bonding wire the certain degree of memory described above.

The internal tube 120 has been described herein and shown in the FIGS. as including the first section 122 with the generally straight or linear shape and the second section 124 that has the generally helical or coiled shape; however, the second section 124 can have one or more of a multitude of shapes. For example, in some implementations, the second section 124 can have any non-linear shape (e.g., coiled, helical, curved, bent, zigzag, serpentine, etc. In some implementations, the second section 124 has a generally helical shape where the revolutions or turns are offset from the central axis of the body 110.

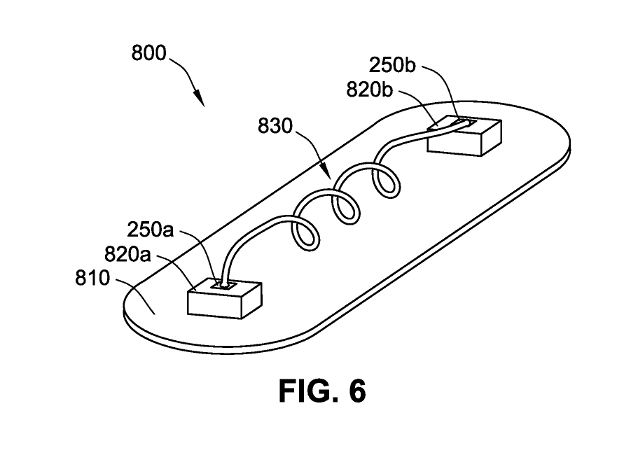

Referring now to FIG. 6, a flexible integrated circuit 800 made and/or formed using one or more of the above described steps and/or processes is shown as including a flexible substrate 810, a first electronic component 820a, a second electronic component 820b, and an interconnect 830. The flexible substrate 810 can be made of any known flexible material suitable for receiving an electronic component thereon, such as, for example, a fabric sheet, a rubber sheet, a flexible plastic sheet, a flexible silicon sheet, etc.

Each of the first and the second first electronic components 820a, 820b can be any electronic component, such as, for example, an integrated circuit, a processor, a controller, a memory device (e.g., EPROM, etc.), a chip, etc. The first electronic component 820a includes a first bond pad 250a, which is the same as, or similar to, the first bond pad 250a described herein. Similarly, the second electronic component 820b includes a second bond pad 250b, which is the same as, or similar to, the second bond pad 250b described herein.

The interconnect 830 is the same as, or similar to, any of the interconnects described herein, such as, for example, interconnect 300, 500, 600, 700b. Additionally, the interconnect 830 can be formed and/or made using any of the steps and/or processes described herein. For example, the interconnect 830 can be made using the process described in reference to FIGS. 2A-2C, the process described in reference to FIGS. 3A-3C, the process described in reference to FIGS. 4A-4D, the process described in reference to FIGS. 5A-5C, or any combination thereof.

While each electrical component 820a, 820b is illustrated as having a single bond pad 250a, 250b, respectively, the present disclosure contemplates multiple bond pads per each electrical component 820a, 820b and multiple interconnects 830 connecting the same.

While the present disclosure has been generally described with reference to creating bonding wires to electrically connect a pair of bond pads, the present disclosure contemplates use of the described techniques and/or processes to form bonding wires into various shapes of antennas and/or coils (e.g., RFID coils). For example, prior RFID coils and/or antennas are typically manufactured from a flexible substrate that typically is made of a stack of polymer layers sandwiched by metal layers (e.g., copper layers). A commonly used stack consists of a layer of polyimide sandwiched by two copper layers. Prior antennas and/or RFID coils required a set of flexible printed circuit boards to manufacture the antennas and/or RFID coils therefrom. Such a process typically involved a subtractive process (e.g., removal of materials) that involves some form of lithography, etching, and/or plating.

Alternatively to such prior methods of antenna formation, the present disclosure provides a method of forming antennas and/or coils using the described capillary tools. That is, RFID coils and/or antennas are made/formed using a direct and additive manufacturing process by forming a bonding wire in an antenna/coil pattern that serves as the turns/traces for the coils and the antennas. The bonding wires can be placed (e.g., using a capillary tool) directly on a substrate (e.g., a flexible and/or stretchable skin adhesive layer) to follow a particular coil/antenna design. The bonding wires can be placed not only on rigid substrates (e.g., FR4, polyimide, polyester, and/or PET), but also on stretchable and/or flexible substrates (e.g., silicone, polyurethane, acrylic, PDMS, etc.). An added benefit of such a process if that the elimination of the prior subtractive process reduces the overall cost of manufacturing coils and antennas.

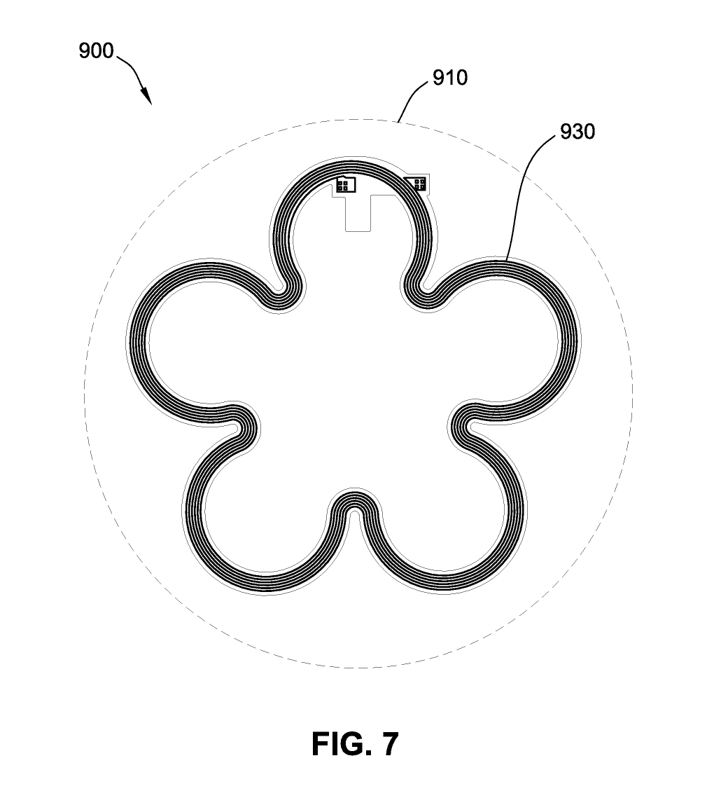

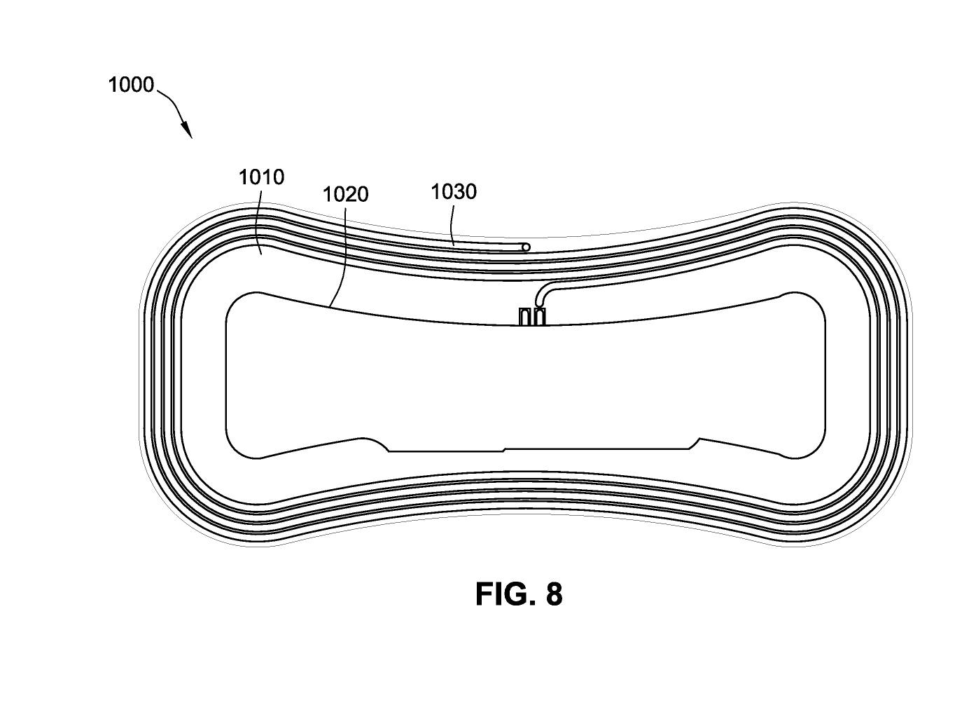

Referring generally to FIGS. 7 and 8, exemplary patterns of antennas and/or coils are shown that can be made/traced using a capillary tool of the present disclosure. Various other patterns are contemplated (e.g., circular, triangular, rectangular, oval, etc.). Referring now to FIG. 7, a flexible integrated circuit 900 made and/or formed using one or more of the above described steps and/or processes is shown as including a flexible substrate 910 and a coil 930 (e.g., antenna). The flexible substrate 910 can be made of any known flexible material suitable for receiving an electronic component and/or the coil 930 thereon, such as, for example, a flexible and/or stretchable skin adhesive layer, a fabric sheet, a rubber sheet, a flexible plastic sheet, a flexible silicon sheet, etc. The coil 930 has a generally clover shape with six turns, although any number of turns is contemplated (e.g., one turn, two turns, five turns, ten turns, one hundred turns, etc.). Additionally, while the coil 930 is shown as being formed of a trace having a certain thickness with a particular spacing between each of the turns of the trace, various other thicknesses and spacing are possible.

Referring now to FIG. 8, a flexible integrated circuit 1000 made and/or formed using one or more of the above described steps and/or processes is shown as including a flexible substrate 1010, one or more integrated circuits 1020, and a coil 1030 (e.g., antenna). The flexible substrate 1010 can be made of any known flexible material suitable for receiving the one or more integrated circuits 1020 and/or the coil 1030 thereon, such as, for example, a flexible and/or stretchable skin adhesive layer, a fabric sheet, a rubber sheet, a flexible plastic sheet, a flexible silicon sheet, etc. The coil 1030 has a generally pinched-rectangular shape (e.g., a generally rectangular shape with the longer sides of the rectangle pinched inward) with four turns, although any number of turns is contemplated (e.g., one turn, two turns, five turns, ten turns, one hundred turns, etc.). Additionally, while the coil 1030 is shown as being formed of a trace having a certain thickness with a particular spacing between each of the turns of the trace, various other thicknesses and spacing are possible (e.g., 25 mil trace with 5 mil spacing therebetween; 12 mil trace with 5 mil spacing therebetween; 5 mil trace with 5 mil spacing therebetween, etc.).

While the present disclosure has been described with reference to one or more particular implementations, those skilled in the art will recognize that many changes may be made thereto without departing from the spirit and scope of the present disclosure. Each of these implementations and obvious variations thereof is contemplated as falling within the spirit and scope of the present disclosure, which is set forth in the following claims. It is also contemplated that additional implementations according to aspects of the present disclosure may combine any number of features from any one or more of the implementations described herein by, for example, adding to a first one of the disclosed implementations one or more elements from one or more other implementations and/or removing one or more elements from the first one of the implementations.

What is claimed is:

1. A capillary tool for use in feeding, bending, and attaching a bonding wire between a pair of bond pads, comprising:
a body having an internal tube extending from a first surface of the capillary tool to a second surface of the capillary tool, the internal tube having a portion with a generally helical shape that includes at least a portion of one complete revolution about a central axis of the body; and
a heating element coupled to the body to provide a heat affected zone along a portion of the internal tube that heats the bonding wire as the bonding wire is fed through the internal tube.

2. The capillary tool of claim 1, wherein the portion of the internal tube having the generally helical shape causes a dispensed portion of the bonding wire to have a generally helical shape that is a function of the generally helical shape of the internal tube.

3. The capillary tool of claim 2, wherein the dispensed portion of the bonding wire includes one or more complete revolutions.

4. The capillary tool of claim 2, wherein the generally helical shape of the dispensed portion of the bonding wire is different than the generally helical shape of the internal tube.

5. The capillary tool of claim 1, wherein the portion of the internal tube having the generally helical shape is designed based on tube geometric design parameters including (i) a tube revolution diameter, (ii) a tube total length of revolutions, and (iii) a tube number of revolutions.

6. The capillary tool of claim 1, wherein the at least a portion of one complete revolution about the central axis of the body includes at least one complete revolution about the central axis of the body.

7. The capillary tool of claim 1, wherein the at least a portion of one complete revolution about the central axis of the body includes at least two complete revolutions about the central axis of the body.

8. The capillary tool of claim 1, wherein the at least a portion of one complete revolution about the central axis of the body includes at least four complete revolutions about the central axis of the body.

9. The capillary tool of claim 1, wherein the at least a portion of one complete revolution about the central axis of the body has a generally constant pitch.

10. The capillary tool of claim 1, wherein the at least a portion of one complete revolution about the central axis of the body has a first portion having a first pitch and a second portion having a second pitch.

11. The capillary tool of claim 1, wherein a first portion of the body has a generally cylindrical shape and a second portion of the body has a generally conical shape, the heating element being coupled to the body in the first portion of the body and the portion of the internal tube having the generally helical shape being positioned in the first portion of the body between the heating element and the second portion of the body.

12. A method for attaching a bonding wire between a pair of bond pads, comprising:
dispensing a portion of the bonding wire from a tip of a capillary tool;
forming a free air ball adjacent to the tip of the capillary tool, the free air ball being formed from at least a portion of the dispensed portion of the bonding wire;
positioning the capillary tool such that the free air ball contacts a first one of the bond pads and at least a portion of the tip of the capillary tool;
using the capillary tool, applying pressure, heat, and ultrasonic energy to the free air ball and to the first bond pad to attach the bonding wire to the first bond pad;
moving the capillary tool towards a second one of the bond pads such that the bonding wire is dispensed from the capillary tool through an internal tube of the capillary tool, the internal tube having a portion with a generally helical shape that includes at least a portion of one complete revolution about a central axis of the capillary tool, the generally helical shape causing at least a portion of the dispensed bonding wire to have a generally helical shape; and
positioning the capillary tool such that a portion of the bonding wire contacts the second bond pad; and
using the capillary tool, applying pressure, heat, and ultrasonic energy to the portion of the bonding wire contacting the second bond pad to attach the bonding wire to the second bond pad.

13. The method of claim 12, wherein the at least a portion of the dispensed bonding wire includes two or more complete revolutions.

14. The method of claim 12, wherein the at least a portion of one complete revolution about the central axis of the capillary tool includes at least one complete revolution about the central axis of the capillary tool.

15. The method of claim 12, wherein the at least a portion of one complete revolution about the central axis of the capillary tool includes at least two complete revolutions about the central axis of the capillary tool.

16. The method of claim 12, wherein the at least a portion of one complete revolution about the central axis of the capillary tool includes at least four complete revolutions about the central axis of the capillary tool.

17. The method of claim 12, wherein the at least a portion of one complete revolution about the central axis of the capillary tool has a generally constant pitch.

18. The method of claim 12, wherein the generally helical shape of the dispensed portion of the bonding wire is different than the generally helical shape of the internal tube.

19. A method for attaching a bonding wire between a pair of bond pads, comprising:
attaching the bonding wire to a first one of the pair of bond pads;
moving the capillary tool around a plurality of posts of a fixture in a generally serpentine path such that the bonding wire is dispensed from the capillary tool through an internal tube of the capillary tool and engages the plurality of posts, the fixture being positioned relative to the pair of bond pads and the capillary tool; and
attaching the bonding wire to a second one of the pair of bond pads.

20. The method of claim 19, further comprising removing the fixture thereby disengaging the bonding wire from the plurality of posts of the fixture, the bonding wire maintaining a generally serpentine shape after the removing.

21. The method of claim 19, further comprising heating the bonding wire during at least a portion of the moving to aid the bonding wire in bending around the plurality of posts of the fixture.

22. The method of claim 19, further comprising, prior to the attaching the bonding wire to the first bond pad:
dispensing a portion of the bonding wire from a tip of a capillary tool;
forming a free air ball adjacent to the tip of the capillary tool, the free air ball being formed from at least a portion of the dispensed portion of the bonding wire;
positioning the capillary tool such that the free air ball contacts a first one of the bond pads and at least a portion of the tip of the capillary tool; and
using the capillary tool, applying pressure, heat, and ultrasonic energy to the free air ball and to the first bond pad to attach the bonding wire to the first bond pad.

23. The method of claim 19, further comprising, prior to the attaching the bonding wire to the second bond pad:
positioning the capillary tool such that a portion of the bonding wire contacts the second bond pad; and
using the capillary tool, applying pressure, heat, and ultrasonic energy to the portion of the bonding wire contacting the second bond pad to attach the bonding wire to the second bond pad.

24. A method for attaching a bonding wire between a pair of bond pads, comprising:
attaching the bonding wire to a first one of the pair of bond pads;
moving the capillary tool around a single post of a fixture at least one time such that the bonding wire is dispensed from the capillary tool through an internal tube of the capillary tool and engages the post, the fixture being positioned relative to the pair of bond pads and the capillary tool;
removing the fixture thereby disengaging the bonding wire from the post, the bonding wire maintaining a generally coiled shape after the removing;
moving the capillary tool towards a second one of the pair of bond pads such that the generally coiled shape of the bonding wire is stretched between the pair of bond pads; and
attaching the bonding wire to the second bond pad.

25. The method of claim 24, further comprising heating the bonding wire during at least a portion of the moving to aid the bonding wire in coiling around the post.

26. A method of making an interconnect for electrically connecting a pair of bond pads, comprising:
attaching a bonding wire to a first one of the pair of bond pads using a capillary tool;
moving the capillary tool towards a second one of the pair of bond pads such that the bonding wire is dispensed from the capillary tool through an internal tube of the capillary tool;
attaching the bonding wire to the second bond pad such that the dispensed bonding wire has a generally arc shape;
engaging the dispensed bonding wire with a fixture such that the fixture causes the dispensed bonding wire to bend into a generally serpentine shape; and
disengaging the fixture from the dispensed bonding wire, the dispensed bonding wire maintaining the generally serpentine shape after the disengaging.

27. The method of claim 26, wherein the fixture includes a first bending member and a second bending member, the engaging including moving the first bending member in a first direction towards the second bending member and moving the second bending member in a second direction towards the first bending member.

28. The method of claim 27, wherein the first bending member includes a base and a plurality of fingers extending therefrom and the second bending member includes a base and a plurality of fingers extending therefrom, the first and the second bending members being offset with respect to each other during the engaging such that the plurality of fingers of the first bending member alternate with the plurality of fingers of the second bending member.

29. A flexible integrated circuit having a flexible substrate, at least two electrical components, and at least one interconnect electrically connecting two of the at least two electrical components, the flexible integrated circuit being formed by a process including:
dispensing a portion of a bonding wire from a tip of a capillary tool;
forming a free air ball adjacent to the tip of the capillary tool, the free air ball being formed from at least a portion of the dispensed portion of the bonding wire;
positioning the capillary tool such that the free air ball contacts a first bond pad of a first one of the at least two electrical components and at least a portion of the tip of the capillary tool;
using the capillary tool, applying pressure, heat, and ultrasonic energy to the free air ball and to the first bond pad to attach the bonding wire to the first bond pad;
moving the capillary tool towards a second bond pad of a second one of the at least two electrical components such that the bonding wire is dispensed from the capillary tool through an internal tube of the capillary tool, the internal tube having a portion with a generally helical shape that includes at least a portion of one complete revolution about a central axis of the capillary tool, the generally helical shape causing at least a portion of the dispensed bonding wire to have a generally helical shape;
positioning the capillary tool such that a portion of the bonding wire contacts the second bond pad; and
using the capillary tool, applying pressure, heat, and ultrasonic energy to the portion of the bonding wire contacting the second bond pad to attach the bonding wire to the second bond pad, thereby electrically connecting the first electrical component with the second electrical component.

30. A flexible integrated circuit having a flexible substrate, at least two electrical components, and at least one interconnect electrically connecting two of the at least two electrical components, the flexible integrated circuit being formed by a process including:
attaching a bonding wire to a first bond pad of a first one of the at least two electrical components using a capillary tool;
moving the capillary tool around a plurality of posts of a fixture in a generally serpentine path such that the bonding wire is dispensed from the capillary tool through an internal tube of the capillary tool and engages the plurality of posts, the fixture being positioned relative to the first bond pad and the capillary tool; and
attaching the bonding wire to a second bond pad of a second one of the at least two electrical components, thereby electrically connecting the first electrical component with the second electrical component.

31. A flexible integrated circuit having a flexible substrate, at least two electrical components, and at least one interconnect electrically connecting two of the at least two electrical components, the flexible integrated circuit being formed by a process including:
attaching a bonding wire to a first bond pad of a first one of the at least two electrical components using a capillary tool;
moving the capillary tool around a single post of a fixture at least one time such that the bonding wire is dispensed from the capillary tool through an internal tube of the capillary tool and engages the post, the fixture being positioned relative to the first bond pad and the capillary tool;
removing the fixture thereby disengaging the bonding wire from the post, the bonding wire maintaining a generally coiled shape after the removing;
moving the capillary tool towards a second bond pad of a second one of the at least two electrical components such that the generally coiled shape of the bonding wire is stretched between the first and the second bond pads; and
attaching the bonding wire to the second bond pad, thereby electrically connecting the first electrical component with the second electrical component.

32. A flexible integrated circuit having a flexible substrate, at least two electrical components, and at least one interconnect electrically connecting two of the at least two electrical components, the flexible integrated circuit being formed by a process including:
attaching a bonding wire to a first bond pad of a first one of the at least two electrical components using a capillary tool;
moving the capillary tool towards a second bond pad of a second one of the at least two electrical components such that the bonding wire is dispensed from the capillary tool through an internal tube of the capillary tool;
attaching the bonding wire to the second bond pad such that the dispensed bonding wire has a generally arc shape, thereby electrically connecting the first electrical component with the second electrical component;
engaging the dispensed bonding wire with a fixture such that the fixture causes the dispensed bonding wire to bend into a generally serpentine shape; and
disengaging the fixture from the dispensed bonding wire, the dispensed bonding wire maintaining the generally serpentine shape after the disengaging.

33. A flexible integrated circuit having a flexible substrate, an electrical component, and a coil electrically connecting with the electrical component, the flexible integrated circuit being formed by a process including:
attaching a bonding wire to a bond pad of the electrical component using a capillary tool; and
forming a coil by moving the capillary tool along a path such that the bonding wire is dispensed from the capillary tool through an internal tube of the capillary tool, the path including two or more turns such that each of the turns of the dispensed bonding wire has a substantially similar shape.

34. The flexible integrated circuit of claim 33, wherein the path includes four or more turns.

35. The flexible integrated circuit of claim 33, wherein the shape is a clover.

36. The flexible integrated circuit of claim 33, wherein the shape is generally rectangular with the longer sides pinched inward.

37. The flexible integrated circuit of claim 33, wherein the shape is a circle.

38. The flexible integrated circuit of claim 33, wherein the forming the coil includes moving the capillary tool around a plurality of posts of a fixture such that the dispensed bonding wire engages the plurality of posts during the moving.

39. The flexible integrated circuit of claim 33, wherein the flexible substrate is an adhesive layer configured to be removably attached to a skin surface of a subject.
